(19) United States
(12) Patent Application Publication
(10) Pub. No.: US 2013/0193545 A1
(43) Pub. Date: Aug. 1, 2013

(54) SEMICONDUCTOR APPARATUS AND IMAGE SENSOR PACKAGE USING THE SAME

(71) Applicant: Samsung Electronics Co., Ltd., Suwon-si (KR)

(72) Inventors: Young-Gyu Jeong, Hwaseong-si (KR); Young-Shin Kwon, Osan-si (KR); Pyoung-Wan Kim, Suwon-si (KR); Seung-Kon Mok, Suwon-si (KR); Hyun-Su Jun, Seongnam-si (KR)

(73) Assignee: Samsung Electronics Co., Ltd., Suwon-si (KR)

(21) Appl. No.: 13/749,178

(22) Filed: Jan. 24, 2013

(30) Foreign Application Priority Data
Jan. 27, 2012 (KR) 10-2012-0008420

(51) Int. Cl. H01L 31/0236; H01L 29/30

(52) U.S. Cl. CPC H01L 31/0236; H01L 29/30
USPC 257/433; 257/622; 257/443

(57) ABSTRACT

A semiconductor apparatus and a method of fabricating the same are provided. The semiconductor apparatus includes a body part having a first surface and a second surface facing each other, a first trench formed into the first surface of the body part, a second trench formed into the second surface of the body part, an opening connecting the first trench and the second trench to each other, a first adhesion enhancer, such as a rough surface, formed on a bottom surface of the first trench, and a second adhesion enhancer, such as a rough surface, formed on the second surface of the body part.

### CROSS-REFERENCE TO RELATED APPLICATION

This application claims priority from Korean Patent Application No. 10-2012-0008420 filed on Jan. 27, 2012 in the Korean Intellectual Property Office, and all the benefits accruing therefrom under 35 U.S.C. 119, the content of which in its entirety is herein incorporated by reference.

### BACKGROUND

1. Field

Embodiments of the present inventive concepts relate to a semiconductor apparatus and an image sensor package using the same.

2. Description of the Related Art

Image sensors have become commonplace in the field of electronics. Their performance and ubiquity increase apace. Image sensors are typically packaged with a holder that includes a glass cover that is attached, generally with an adhesive, to an image-sensor substrate. Air trapped between the glass cover and substrate may expand and contract along with varying environmental conditions, including those conditions to which the package is subjected during manufacturing. Additionally, the glass cover and substrate may have different thermal coefficients of expansion. Expansion and contraction, due to expanding trapped air and thermal expansion of image sensor packaging, may warp the imaging package, degrade the seal between cover and substrate, or delaminate the package, for example. As image sensors become larger, in order to provide improved sensing capabilities, such packaging problems are exacerbated.

### SUMMARY

An exemplary embodiment in accordance with principles of inventive concepts provides a semiconductor apparatus, which can adhesiveness by forming rough surface on an adhesion part of the semiconductor apparatus where a mounting substrate and a transparent member contact

An exemplary embodiment in accordance with principles of inventive concepts also provides an image sensor package having high reliability using the semiconductor apparatus.

These and other objects of an exemplary embodiment in accordance with principles of inventive concepts will be described in or be apparent from the following description of the preferred embodiments.

According to an aspect of an exemplary embodiment in accordance with principles of inventive concepts, there is provided a semiconductor apparatus including a body part having a first surface and a second surface facing each other, a first trench formed into the first surface of the body part, a second trench formed into the second surface of the body part, an opening connecting the first trench and the second trench to each other, a first rough surface formed on a bottom surface of the first trench, and a second rough surface formed on the second surface of the body part.

In some embodiments, a transparent member is disposed in the first trench and covering the opening.

In some embodiments, the first rough surface area and the second rough surface area have substantially the same roughness.

In some embodiments, a corner at which the bottom surface of the first trench and the opening meet, or a corner at which the second surface of the body part and a sidewall of the second trench meet are chamfered.

According to another aspect of an exemplary embodiment in accordance with principles of inventive concepts, there is provided an image sensor package including a semiconductor apparatus including a body part having a first surface and a second surface facing each other, a first trench formed into the first surface of the body part, a second trench formed into the second surface of the body part, an opening connecting the first trench and the second trench to each other, a first rough surface formed on a bottom surface of the first trench, and a second rough surface formed on the second surface of the body part, a first roughness of the first surface of the body part and a second roughness of a bottom surface of the first trench are different from each other, and a third roughness of the second surface of the body part and a fourth roughness of a bottom surface of the second trench are different from each other, a transparent member disposed in the first trench and covering the opening, a mounting substrate connected to the second surface of the body part, and an image sensor chip disposed on the mounting substrate and surrounded by the second trench of the semiconductor apparatus.

In some embodiments, the first roughness and the fourth roughness are substantially the same.

In some embodiments, the second roughness and the third roughness are substantially the same.

In some embodiments, cross-sections of the second roughness and the third roughness exhibit serrated or wavelike shapes.

In some embodiments, a corner at which the bottom surface of the first trench and the opening meet, or a corner at which the second surface of the body part and a sidewall of the second trench meet are chamfered.

In some embodiments, the image sensor package further comprises a first adhesive film connecting the transparent member and the first trench to each other and a second adhesive film connecting the mounting substrate and the second surface of the body part to each other, wherein no portion of the first adhesive film overlaps the bottom surface of the first trench, and no portion of the second adhesive film overlaps the second surface of the body part.

In some embodiments, the semiconductor apparatus further comprises a protruding part protruding from the second surface of the body part, and the mounting substrate includes a recessed part located to correspond to the protruding part.

In some embodiments, an external sidewall of the semiconductor apparatus and the sidewall of the second trench and the second surface of the body part contact, and the distance from an interface between the external sidewall of the semiconductor apparatus and the second surface of the body part to the protruding part is greater than the distance from an interface between the sidewall of the second trench and the second surface of the body part to the protruding part.

In some embodiments, the image sensor package further comprises an adhesive film connecting the first trench and the transparent member to each other, wherein the height from the bottom surface of the first trench to the top surface of the transparent member is greater than the height from the bottom surface of the first trench to the first surface of the body part, and a portion of the adhesive film overlaps the first surface of the body part.

In some embodiments, a groove is recessed from the mounting substrate and at least a portion of the image sensor chip is disposed in the groove.

In some embodiments, the image sensor chip is electrically connected to the mounting substrate by wiring.

An apparatus in accordance with principles of inventive concepts includes: a mounting substrate; a image sensor mounted on the mounting substrate; an upper housing, including upper and lower trenches with an opening therebetween, the upper housing mounted on the mounting substrate; and a transparent member mounted in the upper trench, wherein an adhesion enhancer is formed in a joint between any two of the members including the mounting substrate, the upper housing, and the transparent member.

An apparatus in accordance with principles of inventive concepts includes an adhesion enhancer in the form of a rough surface.

An apparatus in accordance with principles of inventive concepts includes an adhesion enhancer in the form of a protruding member on a first member with a mating recessed part on the member to which the first member is joined.

An apparatus in accordance with principles of inventive concepts includes an adhesion enhancer in the form of a chamfer.

An apparatus in accordance with principles of inventive concepts includes adhesion enhancers in the joints between the transparent member and upper housing and between the upper housing and mounting substrate.

### BRIEF DESCRIPTION OF THE DRAWINGS

The above and other features and advantages of an exemplary embodiment in accordance with principles of inventive concepts will become more apparent by describing in detail preferred embodiments thereof with reference to the attached drawings in which:

FIG. 1 is a perspective view of a semiconductor apparatus in accordance with principles of inventive concepts;

FIG. 2 is a cross-sectional view taken along the line AA of FIG. 1;

FIG. 3 is a plan view of FIG. 1;

FIG. 4 is a bottom view of FIG. 1;

FIGS. 5A to 5D are detailed views of R1 and R2 of FIG. 2, FIG. 6 illustrates that a transparent member is disposed on the semiconductor apparatus shown in FIG. 1;

FIGS. 7 and 8 illustrate a modified example of the semiconductor apparatus shown in FIG. 1;

FIG. 9 is a cross-sectional view of a semiconductor apparatus according to another exemplary embodiment in accordance with principles of inventive concepts;

FIG. 10 is a plan view of the semiconductor apparatus shown in FIG. 9;

FIG. 11 is a bottom view of the semiconductor apparatus shown in FIG. 9;

FIG. 12 is a schematic view of an image sensor package according to another exemplary embodiment in accordance with principles of inventive concepts;

FIGS. 13A and 13B are detailed diagrams of portions ‘O’ and ‘P’ shown in FIG. 12;

FIGS. 14 to 15B are detailed diagrams of a portion ‘Q’ shown in FIG. 12;

FIG. 16 is a cross-sectional view of an image sensor package according to another exemplary embodiment in accordance with principles of inventive concepts;

FIG. 17 is a cross-sectional view of an image sensor package according to another exemplary embodiment in accordance with principles of inventive concepts; and

FIGS. 18 and 19 illustrate a method for manufacturing the image sensor package in accordance with principles of inventive concepts.

### DETAILED DESCRIPTION OF THE EMBODIMENTS

Exemplary embodiments in accordance with principles of inventive concepts will now be described more fully with reference to the accompanying drawings, in which exemplary embodiments are shown. Exemplary embodiments in accordance with principles of inventive concepts may, however, be embodied in many different forms and should not be construed as being limited to the embodiments set forth herein; rather, these embodiments are provided so that this disclosure will be thorough and complete, and will fully convey the concept of exemplary embodiments to those of ordinary skill in the art. In the drawings, the thicknesses of layers and regions may be exaggerated for clarity. Like reference numerals in the drawings denote like elements, and thus their description may not be repeated.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Like numbers indicate like elements throughout. As used herein the term “and/or” includes any and all combinations of one or more of the associated listed items. Other words used to describe the relationship between elements or layers should be interpreted in a like fashion (e.g., “between” versus “directly between,” “adjacent” versus “directly adjacent,” “on” versus “directly on”).

It will be understood that, although the terms “first”, “second”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of exemplary embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of exemplary embodiments. As used herein, the singular forms “a,” “an” and “the” are intended to include the plural forms as well, unless the context clearly indicates otherwise. It will be further understood that the terms “comprises”, “comprising”, “includes” and/or “including,” if used herein, specify the presence of stated features, integers, steps, operations, elements and/or components, but do not preclude the presence or addition of one or more other features, integers, steps, operations, elements, components and/or groups thereof.

Exemplary embodiments in accordance with principles of inventive concepts are described herein with reference to cross-sectional illustrations that are schematic illustrations of idealized embodiments (and intermediate structures) of exemplary embodiments. As such, variations from the shapes of the illustrations as a result, for example, of manufacturing techniques and/or tolerances, are to be expected. Thus, exemplary embodiments in accordance with principles of inventive concepts should not be construed as limited to the particular shapes of regions illustrated herein but are to include deviations in shapes that result, for example, from manufacturing. For example, an implanted region illustrated as a rectangle may have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of exemplary embodiments.

Unless otherwise defined, all terms (including technical and scientific terms) used herein have the same meaning as commonly understood by one of ordinary skill in the art to which exemplary embodiments in accordance with principles of inventive concepts belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

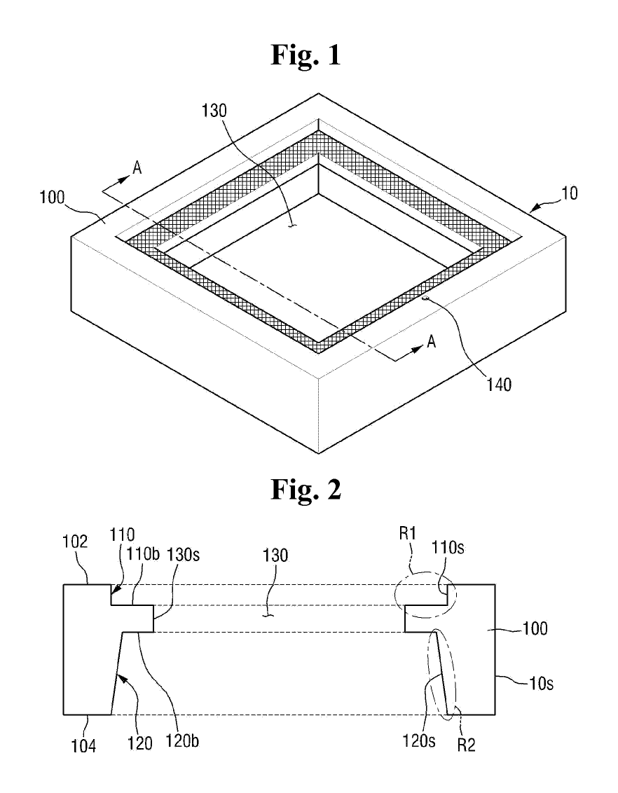

Hereinafter, an exemplary embodiment of a semiconductor apparatus in accordance with principles of inventive concepts will be described with reference to FIGS. 1 to 8.

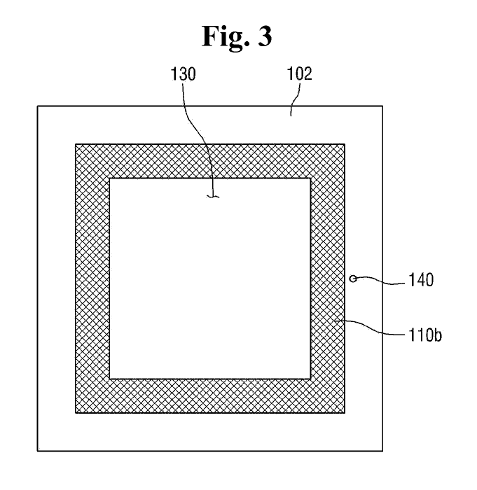

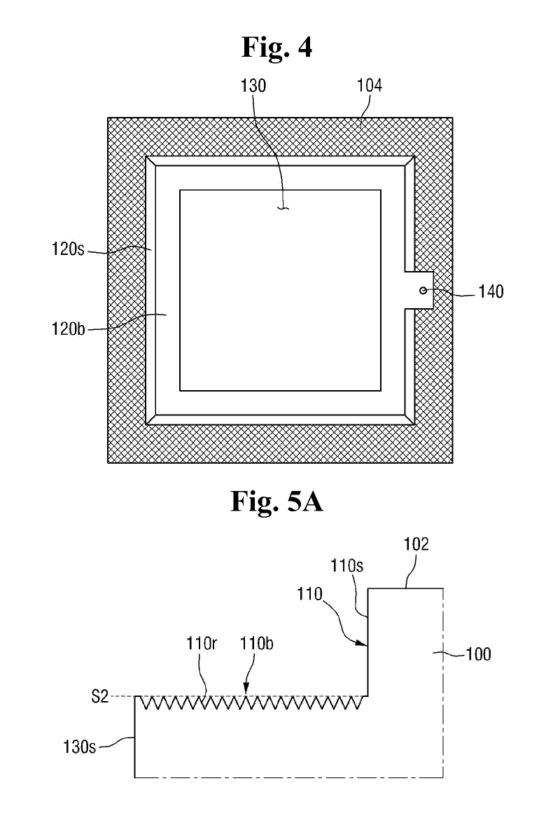

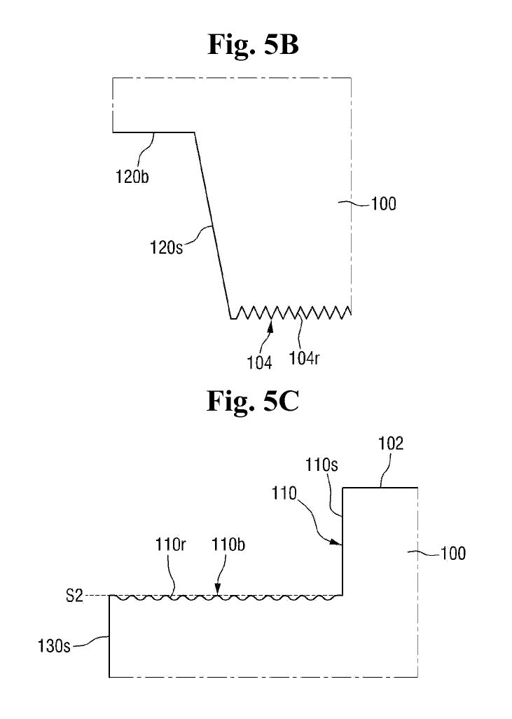

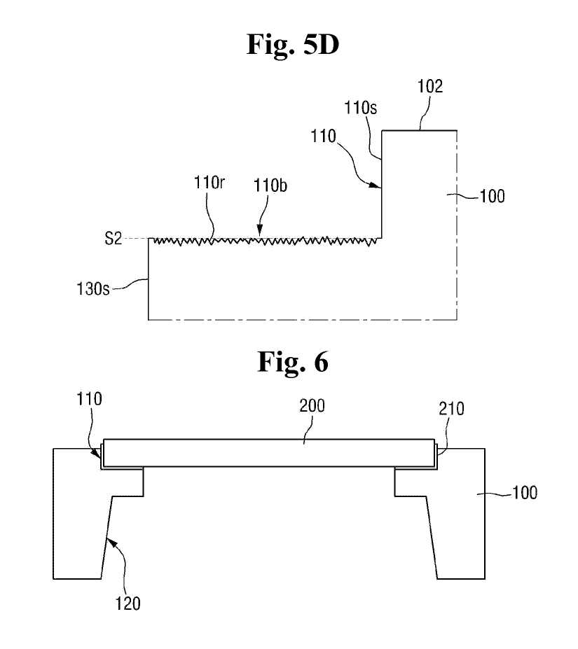

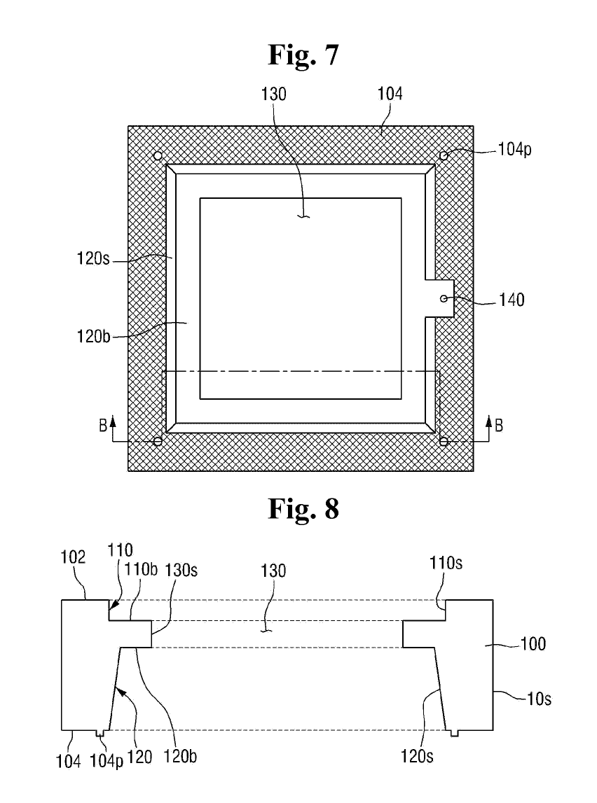

FIG. 1 is a perspective view of an exemplary embodiment of a semiconductor apparatus in accordance with principles of inventive concepts; FIG. 2 is a cross-sectional view taken along the line AA of FIG. 1; FIG. 3 is a plan view of FIG. 1; FIG. 4 is a bottom view of FIG. 1; FIGS. 5A to 5D are detailed views of R1 and R2 of FIG. 2; FIG. 6 illustrates that a transparent member is disposed on the semiconductor apparatus shown in FIG. 1; and FIGS. 7 and 8 are modified examples of the semiconductor apparatus shown in FIG. 1.

Referring first to FIG. 1, the semiconductor apparatus 10 may have, for example, a hexahedral, or regular cuboid, shape, for example. A rectangular opening 130 may be shaped, or formed, in the vicinity of the center of the semiconductor apparatus 10, but inventive concepts do not limit the shape of the opening 130 to a rectangular shape. When an image sensor package is manufactured using the semiconductor apparatus 10, the opening 130 of the semiconductor apparatus 10 may be a path of light incident into a light-receiving part of an image sensor chip. The semiconductor apparatus 10 may include an air vent hole 140. The air vent hole 140 discharges internal gas, generated in the course of manufacturing the image sensor package to the outside of the package. After the image sensor package is manufactured, the air vent hole 140 may be filled with UV epoxy, for example, to seal the image sensor package.

Referring to FIGS. 1 to 5D, the semiconductor apparatus 10 includes a body part 100 (also referred to herein as an upper housing 100), a first trench 110 (also referred to herein as an upper well 110), a second trench 120 (also referred to herein as a lower well 120), an opening 130, a first unevenness, or rough surface, 110r and a second unevenness, or rough surface, 104r. Rough surfaces 110r and 104r are particular examples of adhesion enhancers, which adhesion enhancers may also include chamfers, or protruding parts or members and matching recessed parts, for example, in accordance with principles of inventive concepts. Adhesion enhancers may be mechanically or chemically formed, for example. They may be employed in accordance with principles of inventive concepts in locations where components of a image sensor package in accordance with principles of inventive concepts are joined, for example. The body part 100 has a first surface 102 and a second surface 104 facing each other, or parallel to one another. The first trench 110 may be formed on, or into, the first surface 102 of the body part 100 and the second trench 120 may be formed on, or into, the second surface 104 of the body part 100. The opening 130 may connect the first trench 110 and the second trench 120 to each other. The first rough surface 110r is formed on a bottom surface 110b of the first trench 110 and the second rough surface 104r is formed on the second surface 104 of the body part 100.

In detail, referring to FIG. 2, the first trench 110, the second trench 120, the opening 130, and the first rough surface (110r of FIG. 5A) and the second rough surface (104r of FIG. 5) are formed in the body part 100. The semiconductor apparatus according to embodiments of the present invention is described with regard to a case where rough surface is not formed on the first surface 102 of the body part 100. The body part 100 further includes an external sidewall 10s of the semiconductor apparatus contacting the first surface 102 and the second surface 104. According to embodiments of the present invention, the body part 100 may be formed by, for example, injection molding. Non-limiting examples of the body part 100 may include acryl-based polymer, amine-based polymer and so on. The first and second trenches 110 and 120 of the body part 100 may be formed with the opening 130 using the injection molding. In addition, the first rough surface and the second rough surface may be formed with the first trench 110 using the injection molding. The method of forming the first and second rough surfaces will later be described with reference to FIGS. 5A to 5D. The body part 100 may be made of, for example, a ceramic material. Therefore, the first rough surface and the second rough surface may also be formed in the body part 100 made of a ceramic material.

The first trench 110 formed into the first surface 102 of the body part 100 is downwardly recessed from the first surface 102 of the body part 100. In this exemplary embodiment, the first trench 110 is centrally formed into the first surface 102 of the body part 100. A plane of the first trench 110 may have a square or rectangular shape, for example. The first rough surface is formed on the bottom surface 110b of the first trench 110. The bottom surface 110b of the first trench 110 may be substantially parallel with the first surface 102 of the body part 100. The bottom surface 110b of the first trench 110 is connected to the first surface 102 of the body part 100 through the sidewall 110s of the first trench 110. In this exemplary embodiment in accordance with principles of inventive concepts, the sidewall 110s of the first trench 110 is orthogonal to the first surface 102 of the body part 100. However, the sidewall 110s of the first trench 110 and the first surface 102 of the body part 100 may form another angle, such as an obtuse angle.

The second trench 120 formed into the second surface 104 of the body part 100 is downwardly recessed from the second surface 104 of the body part 100. In this exemplary embodiment in accordance with principles of inventive concepts, the second trench 120 is centrally formed into the second surface 104 of the body part 100. A plane of the second trench 120 may have a square or rectangular shape, for example. The second rough surface may be formed on the second surface 104 of the body part 100 having the second trench 120. However, the rough surface need not be formed in the second trench 120. The semiconductor apparatus according to exemplary embodiments in accordance with principles of inventive concepts will be described with regard to a case where a rough surface is not formed on the second trench 120. When viewed from a top, the bottom surface 120b of the second trench 120 may be included in the bottom surface 110b of the first trench 110b, for example. The bottom surface 120b of the second trench 120 may be substantially parallel with the second surface 104 of the body part 100. The bottom surface 120b of the second trench 120 is connected to the second surface 104 of the body part 100 through the sidewall 120s of the second trench 120. The sidewall 120s of the second trench 120 and the bottom surface 120b of the second trench 120 may form an obtuse angle. However, the sidewall 120s of the second trench 120 and the bottom surface 120b of the second trench 120 may be disposed at other angles, such as a right angle.

The opening 130 connects the first trench 110 and the second trench 120 to each other. That is to say, the opening 130 connects the bottom surface 110b of the first trench 110 and the bottom surface 120b of the second trench 120 to each other. The bottom surface 110b of the first trench 110 is connected to the bottom surface 120b of the second trench 120 through the sidewall 130s of the opening 130. The opening 130 may have a square or rectangular shape, for example.

Referring to FIG. 3, the rectangular opening 130 is surrounded by the bottom surface 110b of the first trench 110. The bottom surface 110b of the first trench 110 is surrounded by the first surface 102 of the body part 100 having a step difference from the bottom surface 110b of the first trench 110. In this exemplary embodiment, the air vent hole 140 is formed into the first surface 102 of the body part 100. In the semiconductor apparatus in accordance with principles of inventive concepts, the sidewall 110s of the first trench 110 and the first surface 102 of the body part 100 are disposed at a right angle, the sidewall of the first trench 110 is not illustrated in FIG. 3. Unlike the first surface 102 of the body part 100, the bottom surface 110b of the first trench 110 is crosshatched, indicating that first rough surface is formed on the bottom surface 110b of the first trench 110. In other words, the first roughness formed on the first surface 102 of the body part 100 is different from the second roughness formed on the bottom surface 120b of the second trench 120. In this exemplary embodiment in accordance with principles of inventive concepts, the first rough surface is entirely formed on the bottom surface 110b of the first trench 110b.

Referring to FIG. 4, the bottom surface 120b of the second trench 120 surrounds the opening 130. In this exemplary embodiment in accordance with principles of inventive concepts, the air vent hole 140 is formed in the bottom surface 120b of the second trench 120. The sidewall 120s of the second trench 120 is formed around the bottom surface 120b of the second trench 120. The second surface 104 of the body part 100 surrounds the bottom surface 120b and the sidewall 120s of the second trench 120. The second rough surface (crosshatched region in this exemplary illustration) is formed on the second surface 104 of the body part 100. A third roughness of the second surface 104 of the body part 100 is different from a fourth roughness of the bottom surface 120b of the second trench 120. In other words, the second rough surface of the second surface 104 of the body part 100 is different from the third roughness and the fourth roughness. In this exemplary embodiment in accordance with principles of inventive concepts, the second rough surface is entirely formed on the second surface 104 of the body part 100. The second rough surface may be partially formed on the second surface 104 of the body part 100, for example.

Referring to FIGS. 2 to 5B, in this exemplary embodiment in accordance with principles of inventive concepts, the first trench 110 and the second trench 120 are formed in the body part 100. The first rough surface 110r is formed on the bottom surface 110b of the first trench 110b and the second rough surface 104r is formed on the second surface 104 of the body part 100. The first rough surface 110r is recessed from a top surface s2 of the bottom surface 110b of the first trench 110 and the second rough surface 104r is recessed from a top surface s1 of the second surface 104 of the body part 100. However, no rough surface is formed on the first surface 102 of the body part 100 and the bottom surface 120b of the second trench 120. In an exemplary embodiment shown in FIGS. 5A and 5B, the first rough surface 110r and the second rough surface 104r are substantially the same, which means that the first and second rough surfaces are substantially the same with respect to shape and size of surface roughness. In this exemplary embodiment in accordance with principles of inventive concepts, the roughness of the rough surfaces may be substantially the same whether or not the same manufacturing processes are employed to form the rough surfaces.

Referring to FIGS. 5A, 5C and 5D, the first rough surface 110r formed on the bottom surface 110b of the first trench 110 may be formed such that a mesh, serrated, or wave-like shape, is repeated, for example. That is to say, a cross-section of the first rough surface 110r may exhibit a repeated serrated or wave-like shape, for example. In FIG. 5A, the serrated shape is triangular, but, the serrated shape may be a rectangular, or a polygonal, for example. As illustrated in the exemplary embodiment of FIG. 5D, the first rough surface 110r formed on the bottom surface 110b of the first trench 110 may have an irregular pattern. Although not shown, the second rough surface formed on the second surface 104 of the body part 100 may have the same shape as the first rough surface 110r formed on the bottom surface 110b of the first trench 110. That is to say, a cross-section of the second rough surface 104r may have a regularly repeated serrated or wave-like shape, for example. The second rough surface 104r may have an irregular cross-sectional shape. However, in accordance with principles of inventive concepts, the first rough surface 110r and the second rough surface (104r of FIG. 5B) may be different from one another.

Referring to FIGS. 5A to 5D, an exemplary method for forming the first rough surface 110r formed on the bottom surface 110b of the first trench 110 and the second rough surface 104r formed on the second surface 104 of the body part 100 will now be described. In an exemplary embodiment in accordance with principles of inventive concepts, the bottom surface 110b of the first trench 110 and the second surface 104 of the body part 100 may be adhered to each other in the semiconductor apparatus. In the following description, an exemplary method for forming rough surfaces in the semiconductor apparatus using injection molding will be described by way of example. In order to form rough surfaces on the adhered surfaces 104 and 110b for mounting a substrate or transparent member, a chemical or physical method may be used, for example. To chemically form the rough surfaces 104r and 110r on the adhered surfaces 104 and 110b, the adhered surfaces 104 and 110b may be etched or corroded, for example. Or, the rough surfaces may be formed on top surfaces of the adhered surfaces by discharging electricity, thereby making the top surfaces of the adhered surfaces 104 and 110b roughened, for example. Or, in order to physically form the rough surfaces 104r and 110r on the adhered surfaces 104 and 110b, the adhered surfaces 104 and 110b may be blustered with sand using a sand blustering method. Or, a desired rough surface may be formed in an injection mold, with the rough surface formed on portions of the semiconductor apparatus through injection molding. In an exemplary embodiment in accordance with principles of inventive concepts, an adhesion enhancer, such as a rough surface, may be formed on the perimeter of the transparent member, in an area where the rough surface would not interfere with or distort light-gathering for an imaging device.

Referring to FIGS. 1 and 6, the semiconductor apparatus 10 may further include a transparent member 200. The transparent member 200 may be disposed in the first trench 110 and may cover the opening 130. The transparent member may be, for example, a glass panel. The transparent member 200 may be adhered to the semiconductor apparatus 10 by an adhesive film 210. The transparent member 200 may be adhered to the bottom surface 110b of the first trench 110 by the adhesive film 210, for example.

Referring to FIGS. 1, 7 and 8, an exemplary embodiment of semiconductor apparatus in accordance with principles of inventive concepts, similar to, or modified from, that shown in FIG. 1 will be described. FIG. 7 illustrates a exemplary embodiment of a semiconductor apparatus similar to that shown in FIG. 1 and FIG. 8 is a cross-sectional view taken along the line BB of FIG. 7.

Referring to FIGS. 1 and 7, the semiconductor apparatus 10 may further include one or more protruding part(s) 104p protruding from the second surface 104 of the body part 100. The protruding part 104p may be formed at an edge interface between the sidewall 120s of the second trench 120 and the second surface 104 of the body part 100, for example. Alternatively, the protruding parts 104p may be formed at arbitrary locations on the second surface 104 of the body part 100. In this exemplary embodiment in accordance with principles of inventive concepts, the second rough surface is not formed on the topmost surface of the protruding part 104p, for example.

Referring to FIG. 8, the protruding part 104p may be formed more closely to the second trench 120, specifically, the sidewall 120s of the second trench 120, than to the external sidewall 10s of the semiconductor apparatus 10. That is to say, the distance from an interface between the external sidewall 10s of the semiconductor apparatus 10 and the second surface 104 of the body part 100 to the protruding part 104p is greater than the distance from an interface between the sidewall 120s of the second trench 120 and the second surface 104 of the body part 100 to the protruding part 104p in an exemplary embodiment. Here, the distance means the minimum distance.

The following description will focus on differences between the semiconductor apparatuses according to the previous and present embodiments, and, for the sake of clarity, repeated contents may be briefly described or omitted.

Referring to FIGS. 1 to 5B, the semiconductor apparatus 10 includes a body part 100, a first trench 110, a second trench 120 and an opening 130. The body part 100 has a first surface 102 and a second surface 104 parallel with, or facing each other. The first trench 110 is formed into the first surface 102 of the body part 100 and the second trench 120 may be formed into the second surface 104 of the body part 100. The opening 130 connects the first trench 110 and the second trench 120 formed in the body part 100 to each other. In this exemplary embodiment of the semiconductor apparatus 10, a first roughness formed on the bottom surface 110b of the first trench 110 is different from a second roughness formed on the second surface 104 of the body part 100 and a third roughness of the second surface 104 of the body part 100 is different from a fourth roughness of the bottom surface 120b of the second trench 120.

Referring to FIGS. 3 and 4, the first roughness of the first surface 102 of the body part 100 and the fourth roughness the bottom surface 120b of the second trench 120 may be substantially the same. In semiconductor apparatus manufactured by injection molding in accordance with principles of inventive concepts, the first surface 102 of the body part 100 and the bottom surface 120b of the second trench 120 may include roughness. If the first surface 102 of the body part 100 and the bottom surface 120b of the second trench 120 are manufactured by the same manufacturing method, the first roughness and the fourth roughness may be substantially the same. The first rough surface of the bottom surface 110b of the first trench 110 makes a difference between the first roughness formed on the first surface 102 of the body part 100 and the second roughness formed on the bottom surface 110b of the first trench 110. In addition, the second rough surface of the second surface 104 of the body part 100 makes a difference between the third roughness of the second surface 104 of the body part 100 and the fourth roughness of the bottom surface 120b of the second trench 120.

Referring to FIGS. 3 and 4, in an exemplary embodiment, a crosshatched region exhibits greater roughness than a non-hatched region. In FIGS. 3 and 4 crosshatching is used to indicate the degree of surface roughness. In exemplary embodiments, rough surfaces may be formed on the first surface 102 of the body part 100 and the bottom surface 120b of the second trench 120 and the roughness of the rough surface formed on the first surface 102 of the body part 100 may be of a lesser degree than the roughness of the rough surface formed on the second surface 104 of the body part 100. In an exemplary embodiment, the first roughness of the first surface 102 of the body part 100 may be different from the second roughness of the bottom surface 110b of the first trench 110b and the third roughness of the second surface 104 of the body part 100 is different from the fourth roughness of the bottom surface 120b of the second trench 120.

Referring to FIGS. 5A and 5B, the second roughness of the bottom surface 110b of the first trench 110b and the third roughness of the second surface 104 of the body part 100 may be substantially the same. In an exemplary embodiment, a semiconductor apparatus in accordance with principles of inventive concepts is manufactured using an injection mold having a serrated rough surface formed on the bottom surface 110b of the first trench 110b and the second surface 104 of the body part 100. Although there may be a process difference, since the bottom surface 110b of the first trench 110b and the second surface 104 of the body part 100 are simultaneously formed, the second roughness and the third roughness may be substantially the same. In an exemplary embodiment, cross-sections of the second roughness and the third roughness may have, for example, serrated or wavelike shapes. However, in exemplary embodiments in accordance with principles of inventive concepts, the second roughness and the third roughness may be different from each other, as will also be applied to a modified example of the semiconductor apparatus shown in FIGS. 6 to 8.

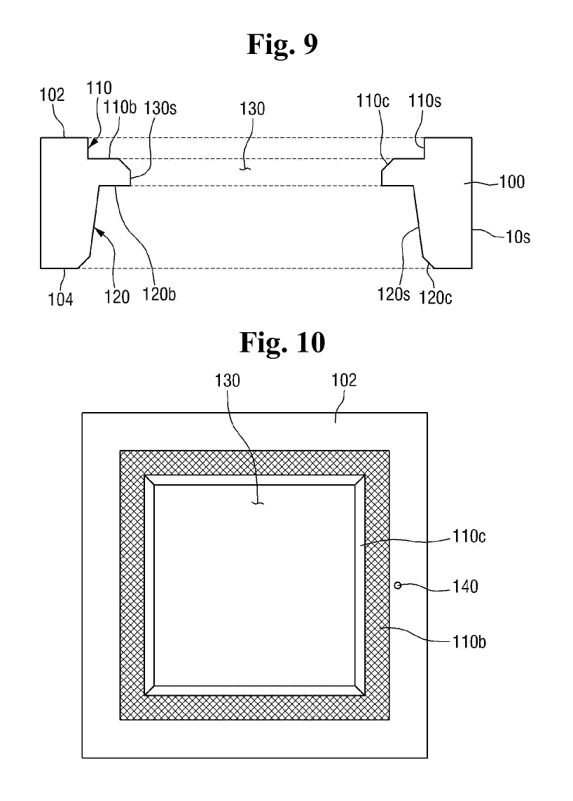

A semiconductor apparatus according to another exemplary embodiment in accordance with principles of inventive concepts will be described with reference to FIGS. 9 to 11. This exemplary embodiment is substantially the same as the semiconductor apparatus according to the previous embodiment shown in FIGS. 6 to 8, except that an adhesion part of the semiconductor apparatus is chamfered. For clarity of description, repeated contents will be briefly described or omitted.

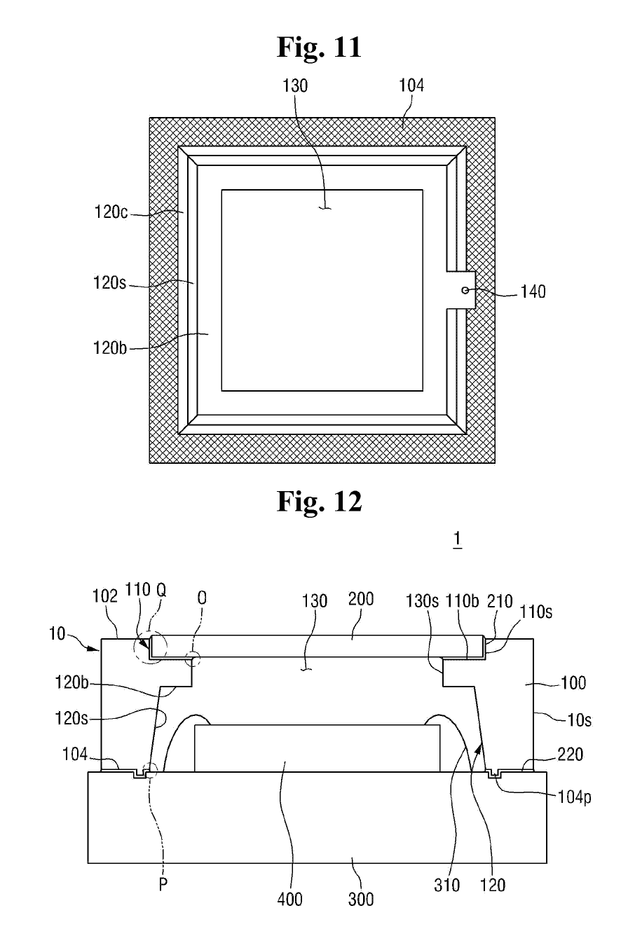

FIG. 9 is a cross-sectional view of a semiconductor apparatus according to another embodiment of the present invention, FIG. 10 is a plan view of the semiconductor apparatus shown in FIG. 9, and FIG. 11 is a bottom view of the semiconductor apparatus shown in FIG. 9.

Referring to FIG. 9, a corner at which the bottom surface 110b of the first trench 110 and the sidewall 130s of the opening 130 meet is chamfered, forming a first chamfered surface 110c. In addition, a corner at which the second surface 104 of the body part 100 and the sidewall 120s of the second trench 120 meet is chamfered, forming a second chamfered surface 120c. In this exemplary embodiment in accordance with principles of inventive concepts, the first chamfered surface 110c and the second chamfered surface 120c are planar, but they may be curved, for example. In the image sensor package, a mounting substrate (300 of FIG. 12) and a transparent member (200 of FIG. 6) may be chamfered at portions adhered to the semiconductor apparatus. In an exemplary embodiment, only one of the corner at which the bottom surface 110b of the first trench 110 and the sidewall 130s of the opening 130 meet, and the corner at which the second surface 104 of the body part 100 and the sidewall 120s of the second trench 120 meet, may be chamfered. That is to say, the semiconductor apparatus may include only one of the first chamfered surface 110c and the second chamfered surface 120c, for example.

Referring to FIGS. 10 and 11, the first chamfered surface 110c may be formed between the periphery of the opening 130 and the bottom surface 110b of the first trench 110. The second chamfered surface 120c may be formed between the sidewall 120s of the second trench 120 and the second surface 104 of the body part 100. In this exemplary embodiment in accordance with principles of inventive concepts, no rough surface is formed on the first chamfered surface 110c and/or the second chamfered surface 120c, for example. In addition, the roughness of the first chamfered surface 110c and the roughness of the bottom surface 110b of the first trench 110 may be different from each other, and the roughness of the second chamfered surface 120c and the roughness of the second surface 104 of the body part 100 may be different from each other, for example.

Referring to FIGS. 12 to 15B, an image sensor package according to another exemplary embodiment in accordance with principles of inventive concepts will be described. Repeated contents will be briefly described or omitted.

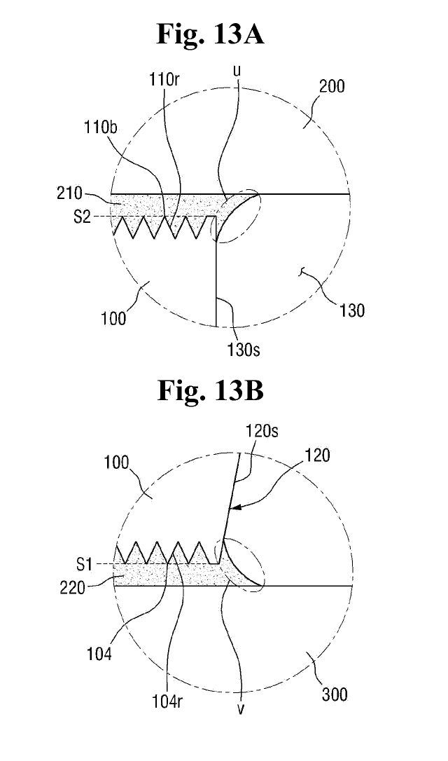

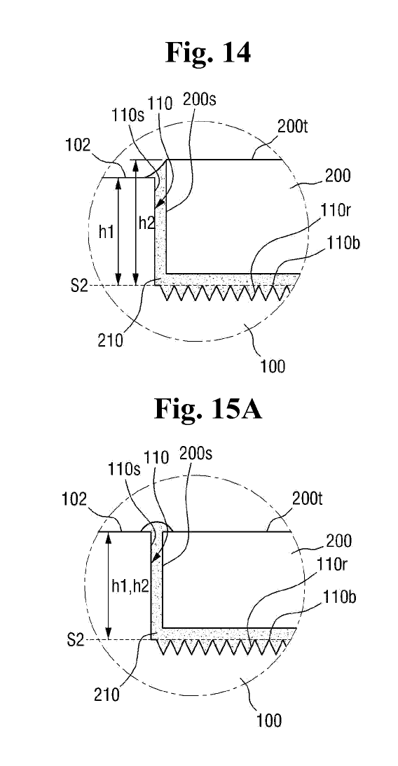

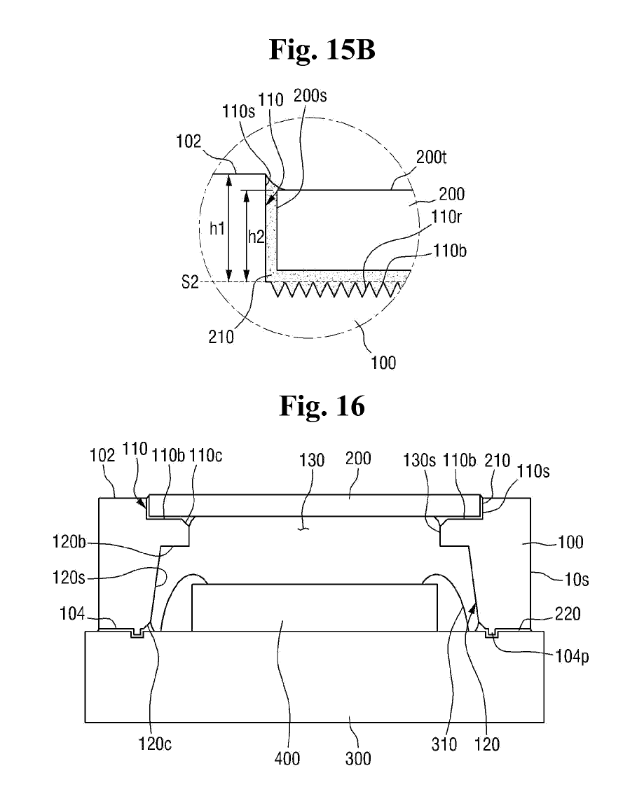

FIG. 12 is a schematic view of an image sensor package according to another exemplary embodiment in accordance with principles of inventive concepts, FIGS. 13A and 13B are detailed diagrams of portions ‘O’ and ‘P’ shown in FIG. 12, and FIGS. 14 to 15B are detailed diagrams of a portion ‘Q’ shown in FIG. 12.

Referring to FIG. 12, the image sensor package 1 includes a semiconductor apparatus 10, a transparent member 200, a mounting substrate 300 and an image sensor chip 400. The image sensor package 1 may include a first adhesive film 210 and a second adhesive film 220. The semiconductor apparatus 10 includes a body part 100, a first trench 110, a second trench 120 and an opening 130. The semiconductor apparatus 10 may include a protruding part 104p formed on a portion contacting the mounting substrate 300.

The first trench 110 may be formed into a first surface 102 of the body part 100 and the second trench 120 may be formed into a second surface 104 of the body part 100. The opening 130 connects the first trench 110 and the second trench 120 formed in the body part 100 to each other. The semiconductor apparatus 10 may include the protruding part 104p protruding from the second surface 104 of the body part 100. In an exemplary embodiment in accordance with principles of inventive concepts, the distance from an interface between an external sidewall 10s of the semiconductor apparatus 10 and the second surface 104 of the body part 100 to the protruding part 104p may be greater than the distance from an interface between a sidewall 120s of the second trench 120 and the second surface 104 of the body part 100 to the protruding part 104p.

Referring to FIGS. 3 and 4, in the semiconductor apparatus 10, a first roughness of the first surface 102 of the body part 100 may be different from a second roughness of a bottom surface 110b of the first trench 110, and a third roughness of the second surface 104 of the body part 100 and a fourth roughness of a bottom surface 120b of the second trench 120 may be different from each other. Referring to FIGS. 5A to 5D, the first roughness of the first surface 102 of the body part 100 may be substantially the same as the fourth roughness of the bottom surface 120b of the second trench 120. The second roughness of the bottom surface 110b of the first trench 110 may be substantially the same as the third roughness of the second surface 104 of the body part 100. Cross-sections of the second roughness and the third roughness may exhibit, for example, serrated or wavelike shapes. The roughness is substantially the same as previously described above with reference to FIGS. 3 to 5D.

Referring to FIG. 12, the body part 100 may be adhered to the transparent member 200 and the mounting substrate 300. The body part 100, the transparent member 200 and the mounting substrate 300 may be adhered to each other to seal the image sensor package 1. In particular, in an exemplary embodiment the transparent member 200 is disposed within the first trench 110. The transparent member 200 is adhered to the first trench 110 via the first adhesive film 210. The transparent member 200 is adhered to the first trench 110 and covers the opening 130. The transparent member 200 disposed in the first trench 110 protrudes with a step difference from the first surface 102 of the body part 100, which will be described with reference to FIGS. 14 and 15B. The transparent member 200 may be made of for example, glass, but is not limited thereto. The body part 100 is disposed on the mounting substrate 300. The mounting substrate 300 is connected to the second surface 104 of the body part 100 with the second adhesive film 220. The mounting substrate 300 may include a recessed part 300p located to correspond to the protruding part 104p. If the semiconductor apparatus 10 does not include the protruding part 104p, the recessed part 300p may not be formed in the mounting substrate 300. The mounting substrate 300 may be a printed circuit board (PCB), for example. The first adhesive film 210 and the second adhesive film 220 may be an epoxy adhesive, for example.

In an exemplary embodiment, the image sensor chip 400 is disposed on the mounting substrate 300 and the image sensor chip 400 is surrounded by the second trench 120 included in the semiconductor apparatus 10. That is, the image sensor chip 400 is positioned in a space formed by the second trench 120. The opening 130 is positioned on the image sensor chip 400. Light passing through the opening 130 is incident into a light receiving part of the image sensor chip 400, where it is detected. The image sensor chip 400 may be attached to a top surface of the mounting substrate 300 by a third adhesive film (not shown). The image sensor chip 400 may be electrically connected to the mounting substrate 300 through wiring 310. The connection using wiring 310 may be performed by a general method or a reverse wiring method, for example. Although FIG. 12 depicts the wiring 310 as not exposed to the outside by the body part 100, aspects in accordance with inventive concepts are not limited thereto. The slope of a sidewall 120s of the second trench 120 and a depth of the second trench 120 may differ depending on the shape of the image sensor chip 400 or the wiring 310, for example. The wiring 310 may be surrounded by a sealing member (not shown) that prevents the wiring 310 from being exposed.

Referring to FIG. 13A, the first adhesive film 210 may be positioned between the transparent member 200 and the bottom surface 110b of the first trench 110. A first rough surface 110r having a triangular cross-section is formed on the bottom surface 110b of the first trench 110 in this exemplary embodiment. The first adhesive film 210 contacts the bottom surface 110b of the first trench 110, the transparent member 200 and a sidewall 130s of the opening 130. When viewed from the top, a portion ‘u’ of the first adhesive film 210 contacting only the sidewall 130s of the opening 130 and the transparent member 200 may not overlap the bottom surface 110b of the first trench 110; that is, it may extend beyond bottom surface 110b. When viewed from a top of the image sensor package, the portion ‘u’ of the first adhesive film 210 may be positioned between the image sensor chip 400 and the bottom surface 110b of the first trench 110 in the form of a band.

Referring to FIG. 13B, the second adhesive film 220 may be positioned between the mounting substrate 300 and the second surface 104 of the body part 100. A second rough surface 104r having a triangular cross-section is formed on the second surface 104 of the body part 100 in this exemplary embodiment. The second adhesive film 220 contacts the second surface 104 of the body part 100, the mounting substrate 300 and the sidewall 120s of the second trench 120. A portion ‘v’ of the second adhesive film 220 contacting only the sidewall 120s of the second trench 120 and the mounting substrate 300 may not overlap the second surface 104 of the body part 100; that is, it may extend beyond the second surface 104. When viewed from a bottom of the image sensor package from which the mounting substrate 300 is removed, the portion ‘v’ of the second adhesive film 220 may be positioned between the second surface 104 of the body part 100 and the sidewall 120s of the second trench 120 in the form of a band.

Referring to FIGS. 13A and 13B, first and second rough surfaces 110r and 104r are formed on the bottom surface 110b of the first trench 110 and the second surface 104 of the body part 100, thereby increasing contact areas with the first and second adhesive films 210 and 220. In particular, bottom surface s2 of the first trench 110, on which the first rough surface 110r is not formed has a much smaller contact area with the first adhesive film 210 than the bottom surface 110b of the first trench 110, on which the first rough surface 110r is formed. In addition, a second surface s1 of the body part 100, on which the second rough surface 104r is not formed, has a much smaller contact area with the second adhesive film 220 than the second surface 104 of the body part 100, on which the second rough surface 104r is formed. As the contact area is increased, adhesion strength is increased. Increasing the contact area may reduce or eliminate delamination of the mounting substrate 300 or of the transparent member 200 in the course of manufacturing the image sensor package.

Referring to FIG. 14, in this exemplary embodiment the height h2 from the bottom surface 110b of the first trench 100 to the top surface 200t of the transparent member 200 is greater than the height h1 from the bottom surface 110b of the first trench 110 to the first surface 102 of the body part 100. In this exemplary embodiment, the height is measured based on the bottom surface s2 when no rough surface is formed on the bottom surface 110b of the first trench 110. A portion of the first adhesive film 210 may be shifted to a top portion of the first surface 102 of the body part 100 to overlap the first surface 102 of the body part 100. In particular, the height h1 from the bottom surface 110b of the first trench 110 to the first surface 102 of the body part 100 may be equal to the height of the first trench 110. The height h2 from the bottom surface 110b of the first trench 100 to the top surface 200t of the transparent member 200 may be equal to a sum of the thickness of the first adhesive film 210 and the thickness of the transparent member 200. If the thickness of the transparent member 200 is greater than or equal to the height of the first trench 110, the height h2 will be greater than the height h1, which is illustrated in FIG. 14. The first adhesive film 210 my be disposed between the sidewall 110s of the first trench 110 and the sidewall 200s of the transparent member 200 and the remaining portion of the first adhesive film 210 may extend to the first surface 102 of the body part 100. FIG. 14 illustrates the first adhesive film 210 positioned to extend to a point where the sidewall 200s of the transparent member 200 and the top surface 200t of the transparent member 200 meet, but aspects in accordance with principles of inventive concepts are not limited thereto. The first adhesive film 210 may expose a portion of the sidewall 200s of the transparent member 200 or may overlap a portion of the top surface 200t of the transparent member 200, for example.

The height relationship the between the transparent member 200 and the first trench 110, illustrated in FIG. 14, may be employed to facilitate a manufacturing process of the image sensor package, but other relationships are contemplated within the scope of inventive concepts. Another exemplary height relationship the between the transparent member 200 and the first trench 110 will be describe with reference to FIGS. 15A and 15B.

Referring to FIG. 15A, the height h2 from the bottom surface 110b of the first trench 100 to the top surface 200t of the transparent member 200 is equal to the height h1 from the bottom surface 110b of the first trench 110 to the first surface 102 of the body part 100. That is to say, in this exemplary embodiment, the height of the first trench 110 is equal to the sum of the thickness of the transparent member 200 and the thickness of the first adhesive film 210. The height relationship illustrated in FIG. 15A may be established by accurately controlling processing conditions. A portion of the first adhesive film 210 may be exposed to the outside between the transparent member 200 and the sidewall 110s of the first trench 110, for example, and the first adhesive film 210 may overlap the first surface 102 of the body part 100 and the top surface 200t of the transparent member 200 at the same time. However, the portion of the first adhesive film 210 overlapping the surface 102 may be removed, for example, by polishing, in the course of manufacturing the image sensor package in accordance with principles of inventive concepts.

Referring to FIG. 15B, the height h2 from the bottom surface 110b of the first trench 100 to the top surface 200t of the transparent member 200 is less than the height h1 from the bottom surface 110b of the first trench 110 to the first surface 102 of the body part 100. That is, in this exemplary embodiment, the height of the first trench 110 is greater than the sum of the thickness of the transparent member 200 and the thickness of the first adhesive film 210. In order to facilitate the manufacturing process, the first adhesive film 210 may entirely surround the sidewall 110s of the first trench 110 and a portion of the first adhesive film 210 may overlap the top surface 200t of the transparent member 200. The first surface 102 of the body part 100 and the top surface 200t of the transparent member 200 may be connected to each other by the first adhesive film 210. In such an exemplary embodiment, the slope of the first adhesive film 210 may gradually change, as illustrated in FIG. 15B.

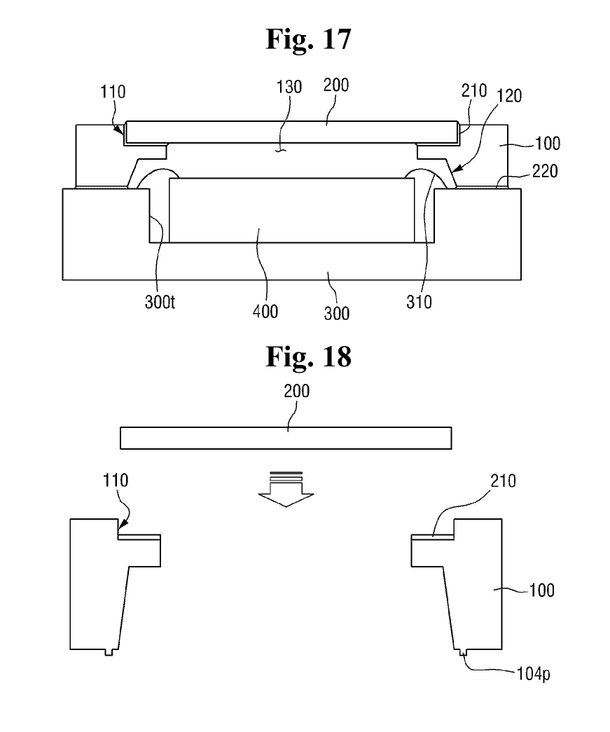

An image sensor package according to another exemplary embodiment in accordance with principles of inventive concepts will be described with reference to FIG. 16. In this exemplary embodiment, the image sensor package according is substantially the same as the image sensor package shown in FIG. 12, except that an adhesion part of the semiconductor apparatus is chamfered. Already-described features will be described briefly or their description will not be repeated here.

In the exemplary embodiment of FIG. 16 a corner at which the bottom surface 110b of a first trench 100 and an opening 130 meet is chamfered and a corner at which a sidewall 120s of a second trench 120 and a second surface 104 of a body part 100 meet is chamfered. A first chamfered surface 110c is positioned between the bottom surface 110b of the first trench 100 and a sidewall 130s of the opening 130. A second chamfered surface 120c is positioned between the sidewall 120s of the second trench 120 and the second surface 104 of the body part 100. A first adhesive film 210 contacts a sidewall 110s of the first trench 110, the bottom surface 110b of the first trench 100, the first chamfered surface 110c and a transparent member 200. A second adhesive film 220 contacts the second surface 104 of a body part 100, a mounting substrate 300, and the second chamfered surface 120c. In this exemplary embodiment in accordance with principles of inventive concepts, both of the first and second chamfered surface 110c and 120c are formed. In an alternative exemplary embodiment, only one of the first and second chamfered surface 110c and 120c may be formed. The first chamfered surface 110c and the second chamfered surface 120c are formed to increase contact areas with the first adhesive film 210 and the second adhesive film 220, thereby increasing adhesion strength of an adhesion part of the image sensor package.

An image sensor package according to another exemplary embodiment in accordance with principles of inventive concepts will be described with reference to FIG. 17. This exemplary embodiment is substantially the same as the image sensor package shown in FIG. 12, except that a protruding part is not formed, and a groove is formed in a mounting substrate. Already-described features will be described briefly or their description will not be repeated here.

In the exemplary embodiment of FIG. 17, a mounting substrate 300 includes a third trench 300t formed thereon to be connected to a second surface 104 of a body part. An image sensor chip 400 is disposed within the third trench 300t. An opening (130 of FIG. 6) may be located to correspond to the third trench 300t.

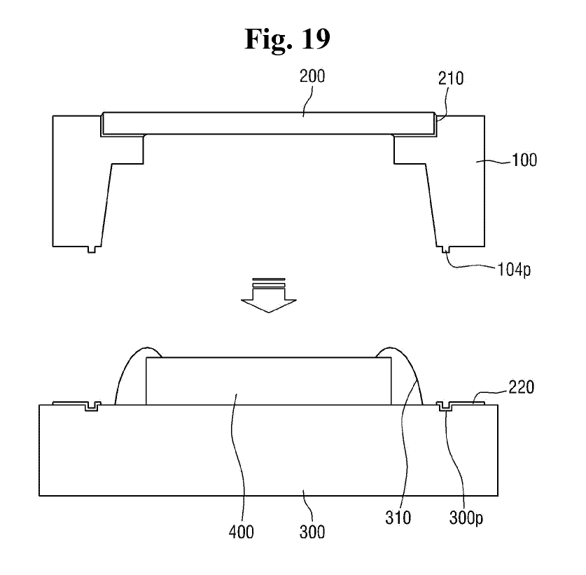

A method for manufacturing an image sensor package according to another exemplary embodiment in accordance with principles of inventive concepts will be described with reference to FIGS. 12, 18 and 19. FIGS. 18 and 19 illustrate a method for manufacturing the image sensor package shown in FIG. 12.

In the exemplary embodiment of FIG. 18, a first adhesive film 210 is formed in a first trench 110 having a first rough surface formed on at least a part of its bottom surface. A transparent member 200 is disposed within the first trench 110. The transparent member 200 is adhered to the body part 100 with the first adhesive film 210. The body part 100 and the transparent member 200 are adhered to each other to manufacture the semiconductor apparatus.

Referring to FIG. 19, an image sensor chip 400 is attached to a top portion of a mounting substrate 300 and is electrically connected to the mounting substrate 300 using a wiring. A second adhesive film may be formed at a portion of the mounting substrate 300 connected to the semiconductor apparatus. The semiconductor apparatus shown in FIG. 18 and the mounting substrate 300 are adhered to each other to complete the image sensor package according to an exemplary embodiment in accordance with principles of inventive concepts.

While exemplary embodiments in accordance with principles of inventive concepts have been particularly shown and described, it will be understood that various changes in form and details may be made therein without departing from the spirit and scope of inventive concepts, as defined by the following claims. It is therefore desired that the present embodiments be considered in all respects as illustrative and not restrictive, reference being made to the appended claims rather than the foregoing description to indicate the scope of inventive concepts.

What is claimed is:

1. A semiconductor apparatus comprising:
a body part having a first surface and a second surface facing each other;
a first trench formed into the first surface of the body part;
a second trench formed into the second surface of the body part;
an opening connecting the first trench and the second trench to each other;
a first rough surface area formed on and covering at least a portion of a bottom surface of the first trench; and
a second rough surface area formed on and covering at least a portion of the second surface of the body part.

2. The semiconductor apparatus of claim 1, further comprising a transparent member disposed in the first trench and covering the opening.

3. The semiconductor apparatus of claim 1, wherein the first rough surface area and the second rough surface area have substantially the same roughness.

4. The semiconductor apparatus of claim 1, wherein a corner at which the bottom surface of the first trench and the opening meet, or a corner at which the second surface of the body part and a sidewall of the second trench meet are chamfered.

5. An image sensor package comprising:
a semiconductor apparatus including a body part having a first surface and a second surface facing each other, a first trench formed into the first surface of the body part, a second trench formed into the second surface of the body part, an opening connecting the first trench and the second trench to each other, a first rough surface area formed on and covering at least a portion of a bottom surface of the first trench, and a second rough surface area formed on and covering at least a portion of the second surface of the body part;
a first roughness of the first surface of the body part and a second roughness of a bottom surface of the first trench are different from each other, and a third roughness of the second surface of the body part and a fourth roughness of a bottom surface of the second trench are different from each other;
a transparent member disposed in the first trench and covering the opening;
a mounting substrate connected to the second surface of the body part; and
an image sensor chip disposed on the mounting substrate and surrounded by the second trench of the semiconductor apparatus.

6. The image sensor package of claim 5, wherein the first roughness and the fourth roughness are substantially the same.

7. The image sensor package of claim 7, wherein the second roughness and the third roughness are substantially the same.

8. The image sensor package of claim 7, wherein cross-sections of the second roughness and the third roughness exhibit serrated or wavelike shapes.

9. The image sensor package of claim 5, wherein a corner at which the bottom surface of the first trench and the opening meet, or a corner at which the second surface of the body part and a sidewall of the second trench meet are chamfered.

10. The image sensor package of claim 5, further comprising a first adhesive film connecting the transparent member and the first trench to each other and a second adhesive film connecting the mounting substrate and the second surface of the body part to each other, wherein no portion of the first adhesive film overlaps the bottom surface of the first trench, and no portion of the second adhesive film overlaps the second surface of the body part.

11. The image sensor package of claim 5, wherein the semiconductor apparatus further comprises a protruding part protruding from the second surface of the body part, and the mounting substrate includes a recessed part located to correspond to the protruding part.

12. The image sensor package of claim 11, wherein an external sidewall of the semiconductor apparatus and the sidewall of the second trench and the second surface of the body part contact, and the distance from an interface between the external sidewall of the semiconductor apparatus and the second surface of the body part to the protruding part is greater than the distance from an interface between the sidewall of the second trench and the second surface of the body part to the protruding part.

13. The image sensor package of claim 5, further comprising an adhesive film connecting the first trench and the transparent member to each other, wherein the height from the bottom surface of the first trench to the top surface of the transparent member is greater than the height from the bottom surface of the first trench to, the first surface of the body part, and a portion of the adhesive film overlaps the first surface of the body part.

14. The image sensor package of claim 5, wherein a groove is recessed from the mounting substrate and at least a portion of the image sensor chip is disposed in the groove.

15. The image sensor package of claim 5, wherein the image sensor chip is electrically connected to the mounting substrate by wiring.

16. An apparatus, comprising:
a mounting substrate;
a image sensor mounted on the mounting substrate;
an upper housing, including upper and lower trenches with an opening therebetween, the upper housing mounted on the mounting substrate; and
a transparent member mounted in the upper trench, wherein an adhesion enhancer is formed in a joint between any two of the members including the mounting substrate, the upper housing, and the transparent member.

17. The apparatus of claim 16, wherein the adhesion enhancer is a rough surface.

18. The apparatus of claim 16, wherein the adhesion enhancer is a protruding member on a first member with a mating recessed part on the member to which the first member is joined.

19. The apparatus of claim 16, wherein the adhesion enhancer is a chamfer.

20. The apparatus of claim 16, wherein adhesion enhancers are included in the joints between the transparent member and upper housing and between the upper housing and mounting substrate.
